(19) United States
(12) Patent Application Publication
(10) Pub. No.: US 2002/0178314 A1
(43) Pub. Date: Nov. 28, 2002

(54) Expansion module and backplane

(76) Inventor: Daniel Y. Cho, Herndon, VA (US)

Correspondence Address: Richard C. Litman, LITMAN LAW OFFICES, LTD., P.O. Box 15035, Arlington, VA, 22215, US

(21) Appl. No.: 10/107,160

(22) Filed: Mar. 28, 2002

Related U.S. Application Data
(60) Provisional application No. 60/293,228, filed on May 25, 2001.

(51) Int. Cl. G06F 13/00; H05K 7/10

(52) U.S. Cl. 710/300

(57) ABSTRACT

An apparatus that is used to expand the capabilities of a single board computer (SBC) or a motherboard. The apparatus is made up of a base module that accommodates the SCB or motherboard at an entrance element and provides a first high speed side connecting element and edge connector and a first expansion module that is connected to the base module by an edge connector attaching to the first high speed side connecting element, the expansion module also providing a peripheral component interconnect (PCI) compliant connecting element and a second high speed side connecting element. Additional expansion modules and components can be added to increase capabilities.

### CROSS-REFERENCE TO RELATED APPLICATION

This application claims the benefit of U.S. Provisional Patent Application Serial No. 60/293,228, filed May 25, 2001.

### BACKGROUND OF THE INVENTION

1. Field of the Invention

The present invention relates to a computer base module and expansion module apparatus and method.

2. Description of Related Art

Computer system design and orientation of desired connector elements and mating elements are important considerations for a computer user. Careful design and spatial features can be the difference between comfortable and efficient use of a given computer system. Ease of expansion can also be an important consideration for a computer user.

U.S. Pat. No. 5,649,100 issued to Ertel et al. outlines the use of local area network concentrators or hubs including concentrators and hubs dedicated to a particular LAN and especially LAN hubs having a backplane dedicated to more than one network. In particular, the system relates to a LAN hub having a backplane which is configurable to one or more access methods, wherein various different modules can be connected to the backplane in a controlled manner for media access, control, bridging, routing and other related functions.

U.S. Pat. No. 5,359,714 issued to Avaneas outlines the use of a computer backplane data path which connects computer backplane modules in a backplane structure. A T-ring made up of T-sections form a ring-like topology, wherein one T-section initiates from each computer backplane module and passively connects other computer backplane modules.

U.S. Pat. No. 5,852,725 issued to Yen outlines the use of a PCI/ISA bus single board computer card using EISA bus connectors and an EISA bus backplane slot for transmitting PCI bus and ISA bus signals. The computer card comprises EISA bus connectors having a first group of connectors interleaved with a second group of connectors. The first group of connectors transmit ISA bus signals and has a structure identical to conventional ISA bus connectors. The second group of connectors transmit PCI bus signals. The backplane comprises a plurality of PCI bus slots, a plurality of ISA bus slots and at least one EISA bus slot.

U.S. Pat. No. 5,951,659 issued to McElroy et al. outlines the use of a communications-oriented computer system backplane, including an input/output bus for transmission of address, data and control information, the input/output bus including a plurality of expansion slot modules connected to the input/output bus for the connection of inputs and outputs. There is a time-domain multiplexed signal bus (TDMSB) for transmission of high speed digitized signal information, the TDMSB for transmission of high-speed digitized signal information, the TDMSB including a plurality of expansion slot modules connected to the TDMSB for the connection of high-speed digitized signal logic cards.

U.S. Pat. No. 6,112,271 issued to Lanus et al., outlines the use of a multiconfiguration backplane, which can be configured in four different configurations. These configurations are a dual configuration, an extended configuration, an active/standby configuration and an active/active configuration. The multiconfigurational backplane has a first COMPACT PCI bus with a first system processor slot, a first bridge slot and a first set of one or more input/output slots. The multiconfiguration backplane has a second COMPACT PCI bus with a second system processor slot, a second bridge slot and a second set of one or more input/output slots.

Great Britain Pat. No. 2,163,305A granted to Johnson et al., outlines the use of a backplane/daughter board connector including a first connector element and a mating second connector element that fits between upwardly extending sidewalls of the first element, the first element being provided with an additional contact carried by one of its sidewalls, and the mating connector element being provided with a further contact carried by a facing outside wall.

Some of these patents already attempt to address better designed backplanes and various extension modules. These patents only partially address these important design issues. Clearly, more work and refining of backplane designs with various buses is needed.

None of the above inventions and patents, taken either singly or in combination, is seen to describe the instant invention as claimed.

### SUMMARY OF THE INVENTION

The invention is an apparatus that is used to expand the capabilities of a single board computer (SBC) or a motherboard. The apparatus is made up of a base module that accommodates the SBC or motherboard at an entrance element and provides a first high speed side connecting element and edge connector and a first expansion module that is connected to the base module by an edge connector attaching to the first high speed side connecting element, the expansion module also providing a peripheral component interconnect (PCI) compliant connecting element and a second high speed side connecting element. Additional expansion modules and components can be added to increase capabilities.

Accordingly, it is a principal object of the invention to develop and better design a computer base module and expansion module apparatus.

It is another object of the invention to provide an easier to use computer base module and expansion module apparatus.

It is a further object of the invention to provide a less expensive computer base module and expansion module apparatus.

Still another object of the invention is to provide an easier to manufacture computer base module and expansion module apparatus.

It is an object of the invention to provide improved elements and arrangements thereof in an apparatus for the purposes described which is inexpensive, dependable and fully effective in accomplishing its intended purposes.

These and other objects of the present invention will become readily apparent upon further review of the following specification and drawings.

### BRIEF DESCRIPTION OF THE DRAWINGS

FIG. 1 is a perspective view of an apparatus according to the present invention.

FIG. 2 is a side perspective view of an apparatus according to the latest invention.

FIG. 3 is an overview of a method of using the apparatus according to the latest invention.

Similar reference characters denote corresponding features consistently throughout the attached drawings.

### DETAILED DESCRIPTION OF THE PREFERRED EMBODIMENT

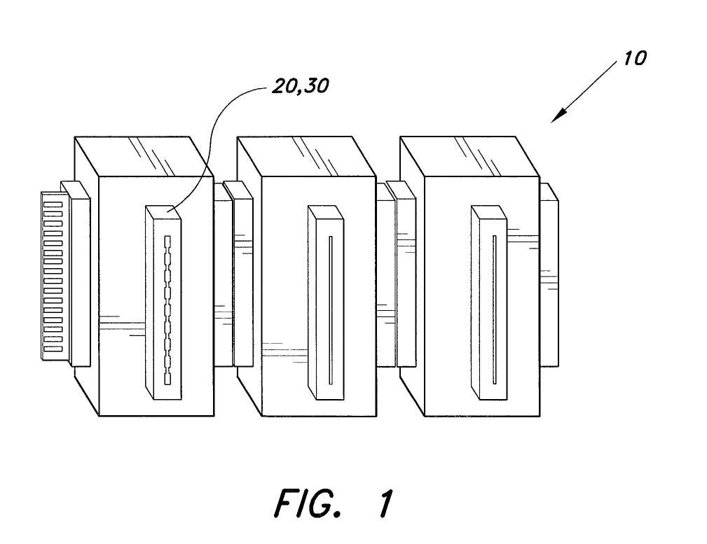

The present invention is an apparatus 10 that is used to expand the capabilities of a single board computer (SBC) 20 or motherboard 30, as shown in FIG. 1.

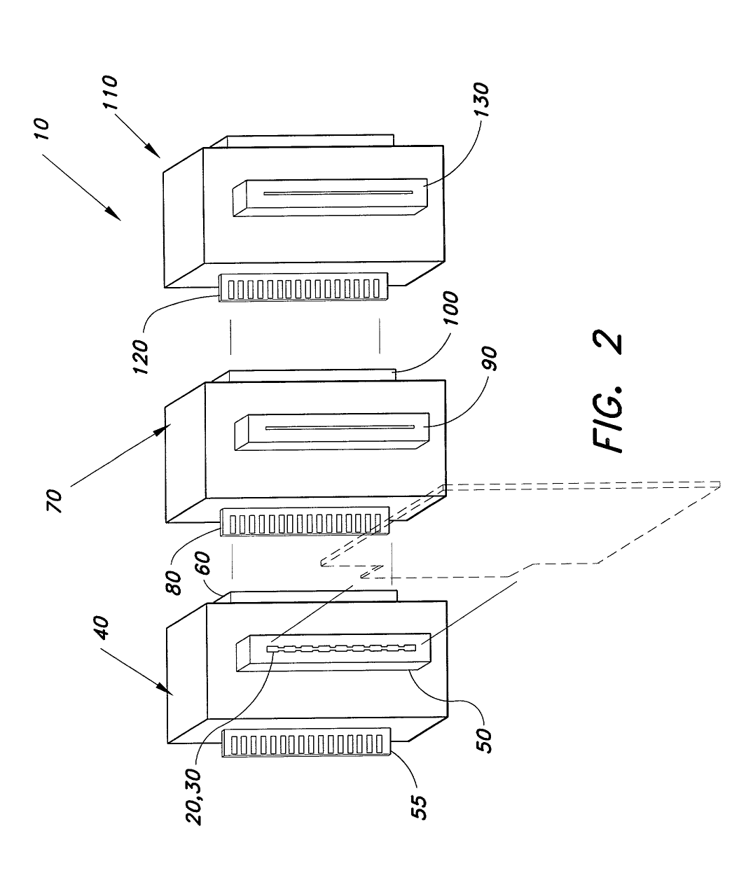

Referring to FIG. 2, the apparatus 10 comprises a base module 40 that accommodates and receives the single board computer 20 or, motherboard 30 at an entrance element 50 and provides an edge connector 55 and a first high speed side connecting element 60. A first expansion module 70 is connected to the base module 40 by an edge connector 80 interleaving with the first high speed side connecting element 60, the first expansion module 70 also providing a peripheral component interconnect (PCI) compliant connecting element 90 and a second high speed side connecting element 100.

Additional expansion modules can be connected in sequence or “piggy backed” together to form a connection chain of power and desired capability for a given user The user can attach additional storage add-on cards such as video cards, internal modems, sound cards, drive controllers and cards that support other peripherals (all attachments not shown). The high speed side connecting elements 60,100 can also accommodate a time-domain multiplexed signal bus (TDMSB).

The technology for ISA and EISA architectures, as well as the TDMSB are well known to those schooled in the related arts, and are not a novel feature of this invention. The various attachments such as a small computer system interface (SCSI) card, add-on cards such as video cards, internal modems, sound cards, drive controllers and cards that support other peripherals (all attachments not shown), are also well known to those schooled in the related arts and are also not novel.

An additional expansion module 110 is attached to the first expansion module 70 at the second high speed side connecting element 100, interleaving the second high speed side connecting element 100 with the edge connector 120 provided on the additional expansion module 110. The additional expansion module 110 has the same PCI compliant connecting element 90 and the high speed connecting element orientation as the first expansion module 70. The PCI compliant connecting element 90 is located on the top of the first expansion module 70 and on the top of the additional expansion module 110. These features are depicted in FIG. 2.

The apparatus 10 is easier and inexpensive to upgrade than a traditional base module. There is no need to open the base module 40 for repairs and it uses commonly available internal components. The apparatus 10 has a small footprint (surface area) and a relatively lower initial cost than a typical base module 40 or personal computer (PC).

The apparatus 10 would be very useful with workers who utilize networked PCs. The base module 40 can be used in lieu of any basic networked PCs being used, and would result in a lower initial cost and allow more desk top and surrounding space for workers. It would also result in lower maintenance costs than utilizing big PCs by replacing faulty components without the need to open the inside of a PC.

Workers using the apparatus 10 would have the base module 40 and would just add onto the base module 40 as they would need to for their various tasks. The base module 40 can be used for simple tasks such as web surfing or word processing, with additional components (expansion modules and other expansion components) being utilized only as needed by the user.

The base module 40 holds a slotless motherboard 30 or single board computer (SBC) 20, with an edge connector 55 and a high speed connecting element 60 on both sides of the motherboard 30 or SBC 20. The base module 40 can be attached to a first expansion module 70 that is T-shaped and has an edge connector 80 and a second high speed side connecting element 100.

The first expansion module 70 is also T-shaped and has a PCI connecting element 90 on top of the first expansion module 70. Commonly available expansion cards (not shown) that are well known to those schooled in the related art can be inserted into the PCI connecting element 90. Additional expansion modules 110 can be attached to the base module 40 or even to the first expansion module 70 that are already attached to the base module 40 in a “piggy back” formation.

The base module 40 should be easy and less expensive to manufacture then a typical base module or PC. The expansion module 70 will be small, since all of the empty space usually reserved for internal expansion of a PC is no longer required. First expansion modules 70 and additional expansion modules 110 should also be simple and inexpensive to manufacture since the expansion module casings would be only slightly bigger than the component that would be placed in it.

The base module 40 has most of the functionality of a PC, only in a very small box. When the PC needs to be expanded, it can be done externally without having to open up a PC unit. The footprint (not shown) of the base module 40 is small, since only necessary space would be used for the base module 40 and any expansion modules 70,110. The initial cost would be low, since only needed parts and components are bought initially. The expansion costs are also low, since a professional technician would be needed to open up a PC unit to expand it. A non-technical person could perform the same upgrade with the apparatus 10, without the cost of a professional technician. Since most internal components are interchangeable, only a few spare components need to be kept for maintenance and support purposes.

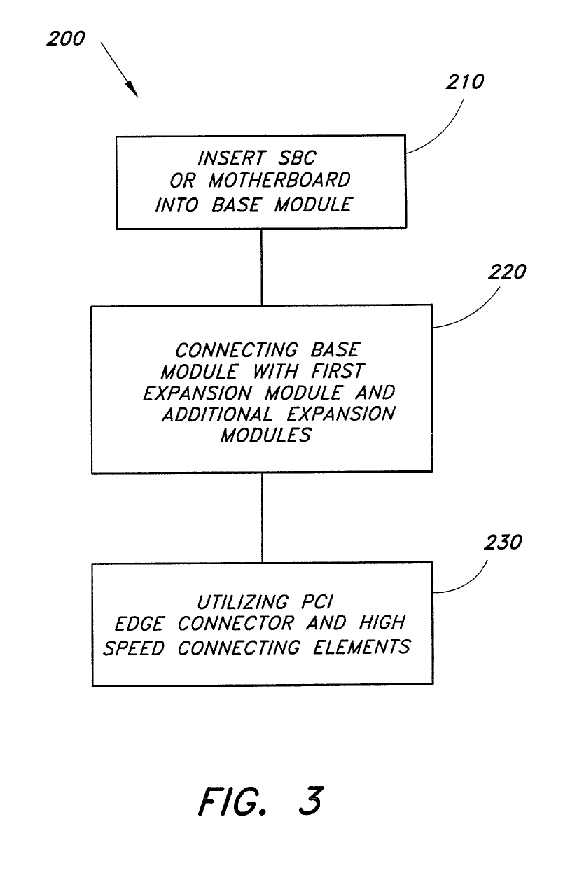

Use of the apparatus 10 is uncomplicated, and is depicted in FIG. 3. FIG. 3 outlines a method 200 that expands the capabilities of a single board computer (SBC) 20 or motherboard 30. The steps include inserting a single board computer 20 or motherboard 30 into the base module 210, connecting the high speed connecting element 60 of the base module 40 with the edge connector 80 from the first expansion module 70, and additional expansion module(s) 220 and utilizing the PCI compliant connecting element(s) 90,130 and the high speed connecting element(s) 60,100 of the first expansion module 70 and the additional expansion module(s) 230.

It is to be understood that the present invention is not limited to the sole embodiment described above, but encompasses any and all embodiments within the scope of the following claims.

I claim:

1. An apparatus that useful to expand the capabilities of single board computer (SBC), comprising:
a base module having an entrance element, a first high speed side connecting element, and a first edge connector, said entrance element being so configured as to accommodate a single board computer at said entrance element; and
a first expansion module having an entrance element, a second high speed side connecting element, and a second edge connector, and being connected to said base module by said second edge connector attaching to said first high speed side connecting element, said expansion module entrance element being a peripheral component interconnect (PCI) compliant connecting element.

2. The apparatus according to claim 1, further comprising at least one additional expansion module attached to said first expansion module at said second high speed side connecting element.

3. The apparatus according to claim 2, wherein said additional expansion module has an identical PCI compliant connecting element and has the same high speed connecting element and edge orientation as said first expansion module.

4. The apparatus according claim 3, wherein said base module and said expansion module(s) are T-shaped.

5. The apparatus according to claim 4, wherein said entrance element and said PCI compliant connecting element is located on the top of each of said first expansion module and said additional expansion module(s).

6. An apparatus that useful to expand the capabilities of a slotless motherboard, comprising:
a base module having an entrance element, a first high speed side connecting element, and a first edge connector, said entrance element being so configured as to accommodate a slotless motherboard at said entrance element; and
a first expansion module having an entrance element, a second high speed side connecting element, and a second edge connector, and being connected to said base module by said second edge connector attaching to said first high speed side connecting element, said expansion module entrance element being a peripheral component interconnect (PCI) compliant connecting element.

7. The apparatus according to claim 6, further comprising at least one additional expansion module attached to said first expansion module at said second high speed side connecting element.

8. The apparatus according to claim 7, wherein said additional expansion module has an identical PCI compliant connecting element and has the same high speed connecting element and edge orientation as said first expansion module.

9. The apparatus according claim 8, wherein said base module and said expansion module(s) are T-shaped.

10. The apparatus according to claim 9, wherein said entrance element and said PCI compliant connecting element is located on the top of each of said first expansion module and said additional expansion module(s).

11. A method for expanding the capabilities of a single board computer or a slotless motherboard, comprising the steps of:
inserting the single board computer or slotless motherboard into a base module;
connecting the first high speed connecting element of the base module with the edge connector from the first expansion module and additional expansion module(s); and
utilizing the PCI compliant connecting element(s) and the high speed connecting element(s) of the first expansion module and the additional expansion module(s).
